(19) United States
(12) Patent Application Publication
(10) Pub. No.: US 2024/0356454 A1
(43) Pub. Date: Oct. 24, 2024

(54) SWITCH MODULE FOR AN INVERTER ARRANGEMENT, INVERTER ARRANGEMENT HAVING THE SWITCH MODULE AND VEHICLE HAVING THE INVERTER ARRANGEMENT

(71) Applicant: ZF Friedrichshafen AG, Friedrichshafen (DE)

(72) Inventor: Ake Ewald, Bayreuth (DE)

(73) Assignee: ZF Friedrichshafen AG, Friedrichshafen (DE)

(21) Appl. No.: 18/687,934

(22) PCT Filed: Sep. 2, 2022
(86) PCT No.: PCT/EP2022/074426

§ 371 Date: Feb. 29, 2024

(30) Foreign Application Priority Data
Sep. 3, 2021 (DE) 10 2021 209 725.1

(51) Int. Cl. H02M 7/00; B60K 11/02; H02M 1/32; H05K 7/20

(52) U.S. Cl. CPC H02M 7/003; B60K 11/02; H02M 1/327; H05K 7/20927

(57) ABSTRACT

A switch module for an inverter assembly in a vehicle includes at least one switch, wherein the switch is a high-side switch or low side switch, an input connection for an intermediate circuit capacitor and an output connection for a phase output, and a body, wherein the body has at least one module main surface, wherein the switch is on the main surface of the module, and wherein the input connection and output connection are on opposite sides of the switch module, and/or extend along the X-axis.

The invention relates to a switch module that has the features in the preamble of claim 1. The invention also relates to an inverter assembly that contains the switch module and a corresponding vehicle.

Inverters are needed for the drives in electric vehicles and hybrid vehicles, with which an alternating current is generated from the direct current provided by a battery or generator, in order to power an electric motor in a vehicle. The core components of the inverter are switches with which electrical connections are established or disconnected, depending on the phasing. In particular, semiconductor switches are used that can withstand the switching frequency as well as the switching current, but become hot in operation and therefore must be placed appropriately for their use.

In the prior art, the switches are placed adjacent to one another on a surface, such that they can be actively cooled from below and passively cooled from above through convection and/or thermal radiation.

The object of the present invention is to create a switch module for an inverter assembly in a vehicle that can be integrated particularly easily therein. This problem is solved by a switch module that has the features of claim 1, an inverter assembly that has the features of claim 9 and a vehicle that has the features of claim 15. Preferred embodiments of the invention can be derived from the dependent claims and the description in conjunction with the drawings.

A switch module is proposed with the invention that is designed and/or suitable for use in an inverter assembly in a vehicle. The vehicle is an electric vehicle or hybrid vehicle. The vehicle contains at least one traction motor with which the vehicle is powered. The traction motor is an electric motor.

The inverter assembly generates an alternating current from a direct current.

The switch module contains one or more switches. There can therefore be either exactly one switch or two or more switches in the switch module. The switches can be either high-side switches or low-side switches. If the switch module contains two or more switches, at least one can be a high-side switch and at least one can be a low-side switch.

The inverter assembly contains two intermediate circuit capacitors and at least one phase output. The switch module has an input connection for contact with the intermediate circuit capacitor and an output connection for contact with the at least one phase output. Specifically, the high-side switch is or can be connected to the DC(+) output in the intermediate circuit capacitor and/or the low-side switch is or can be connected to the DC(−) output on the intermediate circuit capacitor through an input connection.

The switch module has a body that forms at least one main surface of the module. The switch is placed on the main surface of the module or is at least parallel thereto. The main surface is preferably the surface of the switch module and/or the body thereof that has the largest surface area. The switch module and/or body thereof can also have two main surfaces on opposite sides. A first main surface can be on the front of the switch module and/or body thereof, and the second main surface can be on the back. Lateral surfaces encompass the module, which are smaller, i.e. preferably significantly smaller than the main surface(s). In particular, the switch module can have a housing that forms the body, or a part thereof.

It is proposed within the framework of the invention that the input connection and output connection be on opposite sides of the switch module and/or extend in both directions along the Y-axis. The vertical direction is defined by the Z-axis, and the thickness of the switch module extends along the X-axis.

One consideration of the invention is to design the switch module such that the input connection and output connection are symmetrically placed, to ensure that that it can be particularly easily integrated in the inverter assembly. In particular, the switch module can be placed in the inverter assembly from above.

The switch module preferably contains a cooling element that is parallel to the main surface of the module and/or extends along the plane defined by the Y and Z-axes. The cooling element is preferably an active cooling element, specifically a liquid cooling element. In particular, the cooling element is dedicated specifically and/or exclusively to the switch module.

The cooling element preferably has a cooling connection that extends downward along the Z-axis. Consequently, the cooling connection is on one of the lateral surfaces of the switch module. This further enables the switch module to be placed in the inverter assembly from above.

In a preferred version of the invention, the switch module contains a control and/or measurement connection, which extends upward along the Z-axis. In particular, the control and/or measurement connection is on the side opposite the cooling connection. Consequently, the control and/or measurement connection is on another lateral surface, in particular the opposite side, of the switch module. This also contributes to being able to place the switch module in the inverter from above.

On the whole, two opposing surfaces of the switch module are used for the input and output connections, and the other two opposing surfaces are used for the cooling connection and the control and/or measurement connection. Consequently, each lateral surface of the switch module has a different function. By using the lateral surfaces for the connections, the switch module can be kept thin, such that it does not occupy a great deal of space in the inverter assembly, and can be placed therein from above.

The switch module preferably has at least one power semiconductor forming a switch. This power semiconductor is preferably parallel to the main surface of the module, and/or extends along the Y-Z plane. Particularly preferably, the power semiconductor does not have a housing. The semiconductor can be made of, e.g., Si, SiC, GaN, etc. It can be an IGBT, MOSFET, or cascode, etc.

The switch module preferably has a ceramic/copper printed circuit board, which is parallel to the main surface of the module, and/or parallel to the Y-Z plane. The ceramic/copper printed circuit board is preferably a DCB (Direct Copper Bonding) substrate or an IMS (Insulated Metal Substrate). The ceramic/copper printed circuit board is particularly advantageous for the removal and/or discharge of thermal energy. The switch or switches, in particular in the form of power semiconductors, are preferably placed directly on the ceramic/copper printed circuit board, in particular soldered thereto. The cooling element is in contact with the ceramic/copper printed circuit board. By way of example, the cooling element spans the entire surface area of the ceramic/copper printed circuit board. The ceramic/copper printed circuit board is preferably rectangular.

In a preferred version of the invention, the input connection has an input contact surface and the output connection has an output contact surface that is preferably in the same plane as the input contact surface. The phase output has a complementary output contact surface, which is preferably in the same plane as the output contact surface.

This design allows the switch module to come in contact with the complementary contact surface when pushed downward, thus forming an electrical connection. The cooling connection can also face upward, such that when the switch module is pushed downward against a complementary cooling connection on the cooling element in the inverter assembly, a fluid connection for the cooling element is established. This also allows the switch module to be placed in the inverter assembly from above.

In another version of the invention, the switch module contains at least one high-side switch and at least one low-side switch. In particular, this switch module forms a half bridge. With this design, a phase output can be supplied over all phases by a single, space-saving switch module. There can also be two or more of these switch modules for each phase output.

If the switch module has two switches, one of which is a high-side switch and the other is a low-side switch, this switch module preferably has two ceramic/copper printed circuit boards populated by switches, with the cooling element in between the switches and/or the ceramic/copper printed circuit boards, such that both switches can be cooled actively. This results in a sandwich structure for the switch module.

The inverter assembly for the vehicle is also part of the invention, which contains numerous switch modules like those described above, and/or according to claims 1 to 8. Different types of switch modules can also be used in the inverter assembly.

The purpose of the inverter assembly is to obtain alternating current from direct current.

The inverter assembly contains the intermediate circuit capacitor and at least one of the phase outputs, and the switches and/or switch modules can be connected at the input side to the intermediate circuit capacitor and at the output side to the at least one phase output. The inverter assembly preferably has exactly three phase outputs for a three-phase alternating current. The switches are connected at the input side to the intermediate circuit capacitor and at the output side to the at least one phase output. A preferably three-phase alternating current can be generated with this design and the appropriate activation of the switch module and/or switches.

It is proposed that numerous switch modules be in the inverter assembly in a stack or a row, such that their main surfaces are parallel to one another. This results in a parallel horizontal or vertical arrangement of the switch modules, in which they are placed on edge in the inverter assembly. The switch modules are preferably congruent to one another, or at least overlap, when viewing the main surface of the module from above. In particular, the switch modules are stacked, preferably with a spacing between them.

The fundamental concept under consideration here is based on the previous placement of the switch modules in the same plane, adjacent to one another, such that they can be actively cooled from behind, and passively cooled from in front through convection and thermal radiation. This has the disadvantage that it requires a relatively large amount of space, and can also result in problems with regard to the lengths of the various wires used to connect the high-side switches and low-side switches when they are placed in this configuration. The inverter assembly according to the invention exploits a three dimensional structure, thus reducing the amount of space needed for the switch modules in the inverter assembly. This space-saving arrangement is obtained through the specific design of the switch modules.

In a preferred version of the invention, the inverter assembly contains one or more fasteners with which the switch modules are secured in place vertically. In particular, the switch module is held down by the fasteners, such that the input contact surfaces and the output contact surfaces, and/or the cooling connection are aligned with the appropriate contacts. The fastener(s) are preferably strips extending horizontally, along the X-axis.

All of the control and/or measurement connections on the switch module preferably extend in the same direction in the inverter module, such that the contact can be established with the entire switch module from one side.

The inverter assembly preferably contains a control and/or measurement printed circuit board, which is placed on the numerous switch modules and the control and/or measurement connections that face upward can be received in the control and/or measurement printed circuit board. This simplifies the contacts for the switch module, and results in a space-saving structure.

In a preferred version of the invention, the parallel main surfaces of the switch modules are parallel to the Y-Z plane, and/or parallel to one another. The main surface or extension of the intermediate circuit capacitor is parallel to the X-Y plane. The main surface of the capacitor is the side of the intermediate circuit capacitor with the greatest surface area. The main surfaces of the modules are therefore perpendicular to the main surface of the capacitor. This allows for the switch modules to be placed parallel to one another, in a space-saving manner, on a lateral surface of the intermediate circuit capacitor.

All of the control and/or measurement connections on the switch module in the inverter assembly preferably extend in the same direction, such that contact to the entire switch module can be obtained from one side.

The inverter assembly preferably contains a control and/or measurement printed circuit board that is placed on the numerous switch modules such that the upward-facing control and/or measurement connections can be received in the control and/or measurement printed circuit board. This makes it easier to form the contacts to the switch modules and results in a space-saving structure.

In a preferred version of the invention, the main surfaces of the switch modules are parallel to the Y-Z plane and/or parallel to one another. The main surface of the intermediate circuit capacitor is parallel to the X-Y plane. The main surface of the capacitor is the surface of the intermediate circuit capacitor that has the greatest surface area. The main surfaces of the modules are therefore perpendicular to the main surface of the capacitor. As a result, the switch modules can be placed in a space-saving manner on a lateral surface of the intermediate circuit capacitor, parallel to one another.

From a functional perspective, each phase output preferably has at least one dedicated high-side switch and at least one dedicated low-side switch. This means that a complete phase can be connected to and/or generated with each phase output.

In a preferred version of the invention, each phase output has two or more dedicated high-side switches and/or two or more low-side switches.

In a first alternative of the invention, all of the high-side switches for the same phase output are adjacent to one another, and/or all of the low-side switches for the same phase output are adjacent to one another. This results in a group of high-side switches and a group of low-side switches that are adjacent to one another.

This design has the advantage that it is very easy to connect the intermediate circuit capacitor.

In an alternative design, the high-side switches and low-side switches are symmetrical to one another over a central plane. The central plane extends in the Y-Z plane, thus separating the switches for a phase output symmetrically. In particular, at least one high-side switch is placed between two low-side switches. There can also be two or more high-side switches between two low-side switches. At least one low-side switch can also be placed between two high-side switches at the phase output. There can also be two or more low-side switches between two high-side switches at the phase output. This symmetrical arrangement has the advantage of minimal, commutating cells, reducing the necessary compensating currents in the intermediate circuit for the intermediate circuit capacitor.

The invention also relates to a vehicle with the inverter assembly described above, or in accordance with any of the preceding claims. The vehicle contains at least one traction motor, and the inverter assembly is designed to generate alternating current for the traction motor, and/or supply the traction motor with AC voltage and alternating current.

The following description and drawings disclose preferred exemplary embodiments of the invention. Therein:

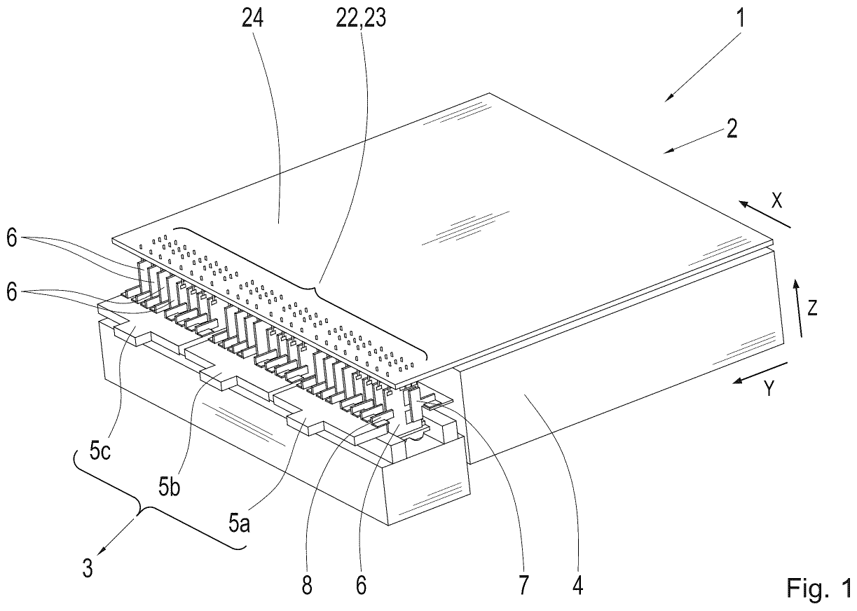

FIG. 1 shows a schematic, three dimensional illustration of an inverter assembly forming an exemplary embodiment of the invention;

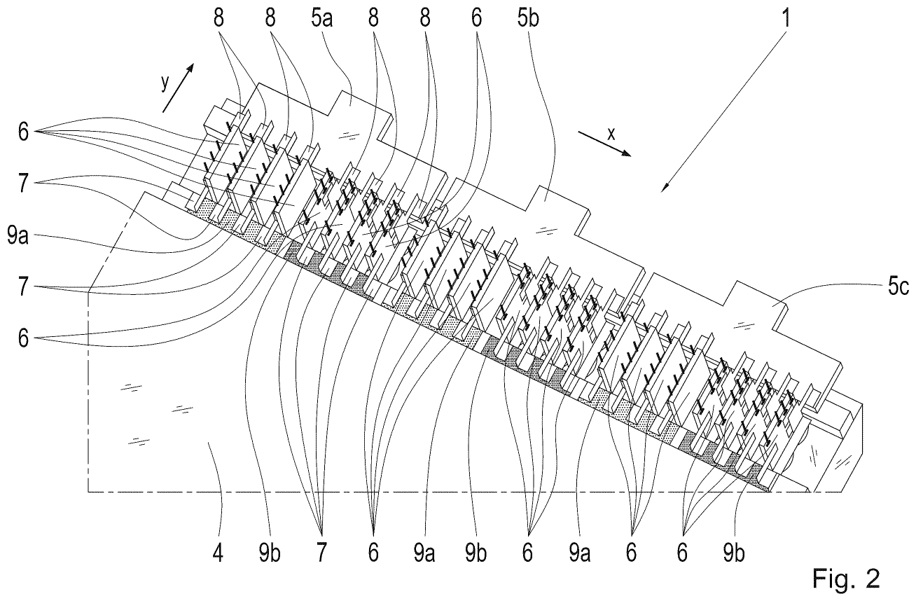

FIG. 2 shows a detail of the inverter assembly in FIG. 1;

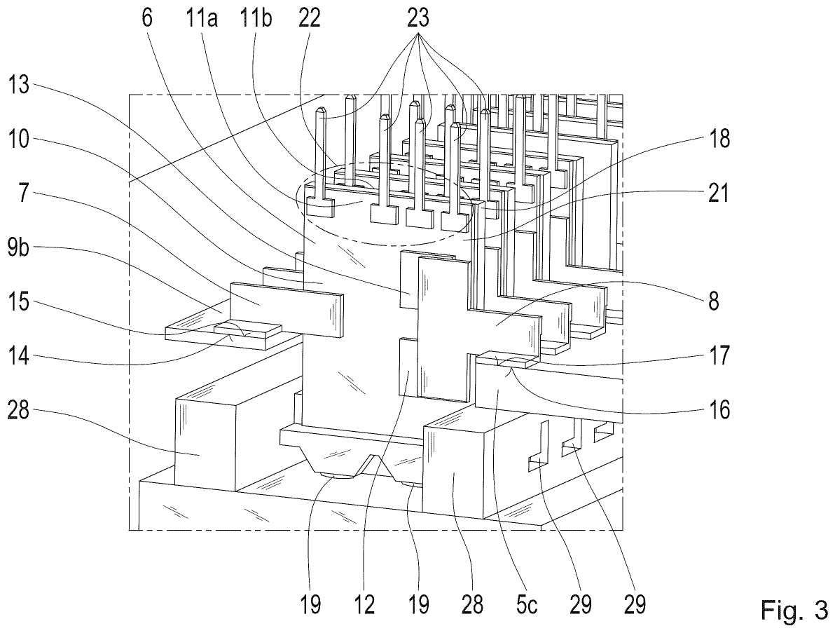

FIG. 3 shows another detail of the inverter assembly shown in the preceding figures;

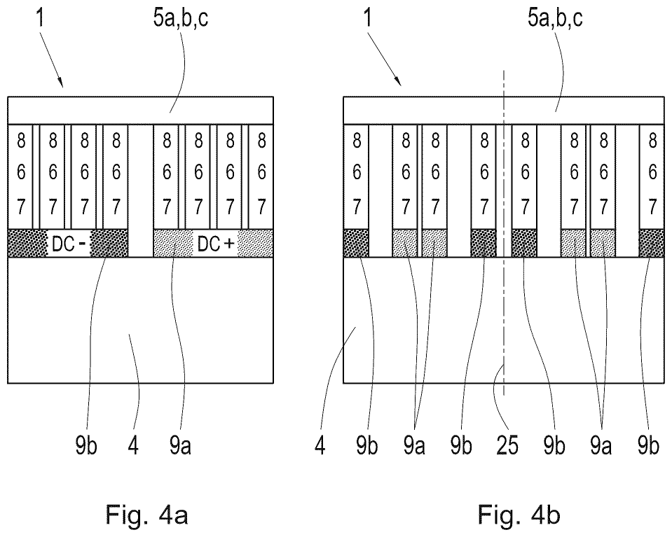

FIGS. 4a, dd b show a schematic view from above of a connecting region on the inverter assembly in the preceding figures, with different arrangements of the switch modules;

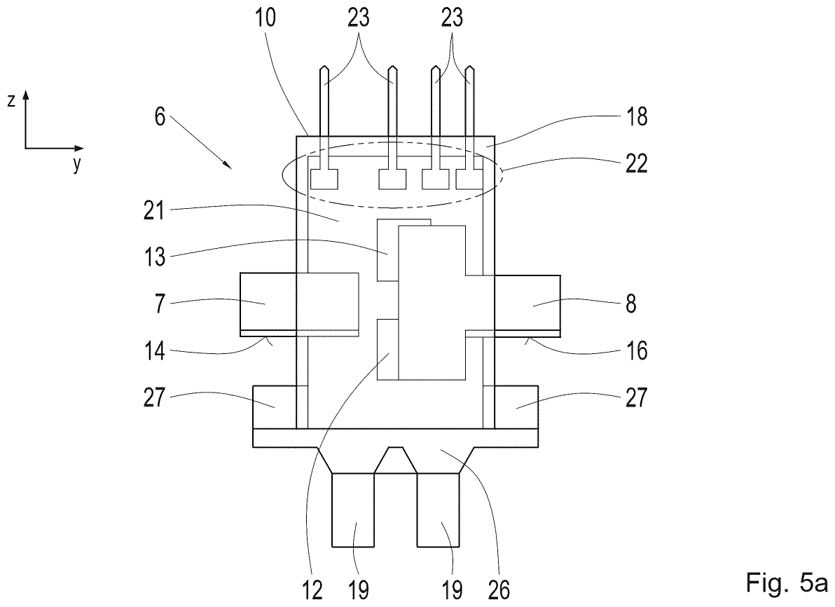

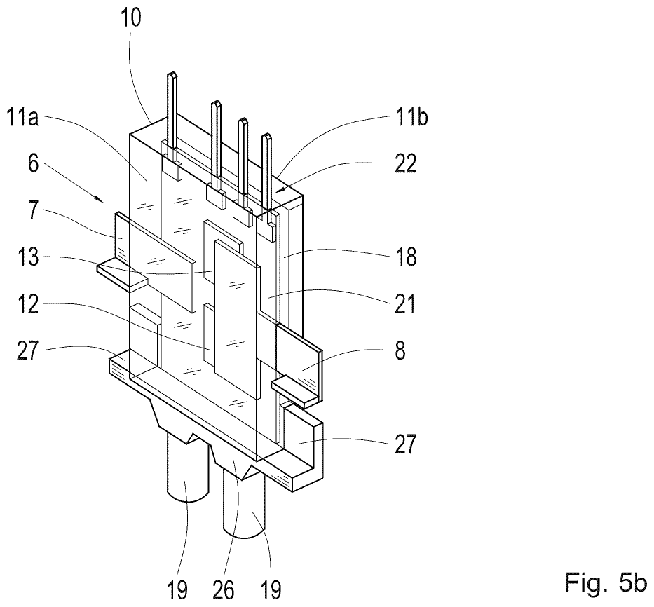

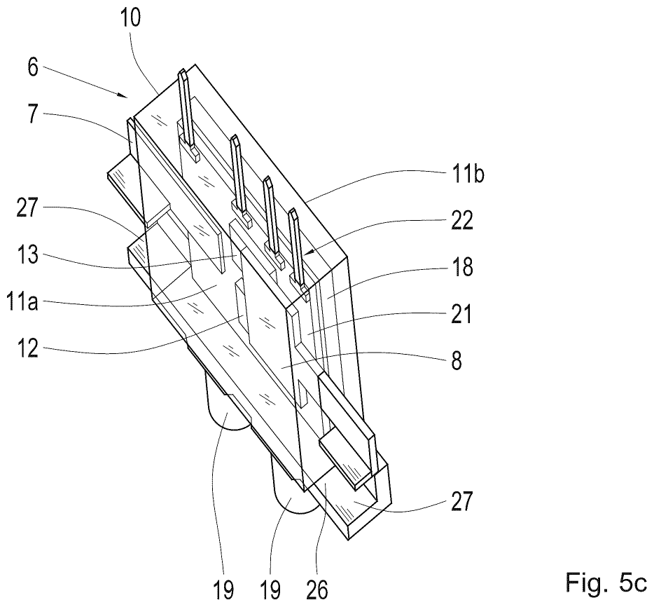

FIGS. 5a, b, c show three dimensional illustrations of a switch module for the inverter assembly from different perspectives, forming an exemplary embodiment of the invention;

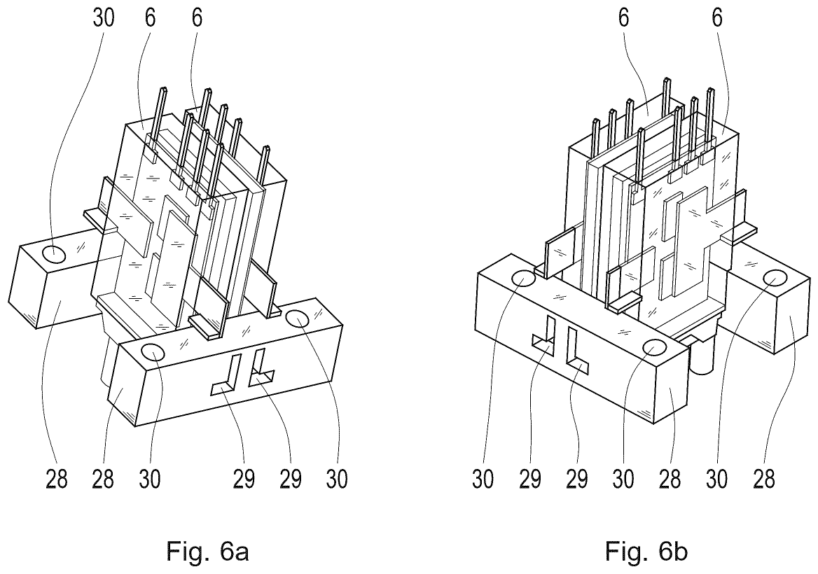

FIGS. 6a, b show three dimensional illustrations of the switch module from different perspectives when it is installed;

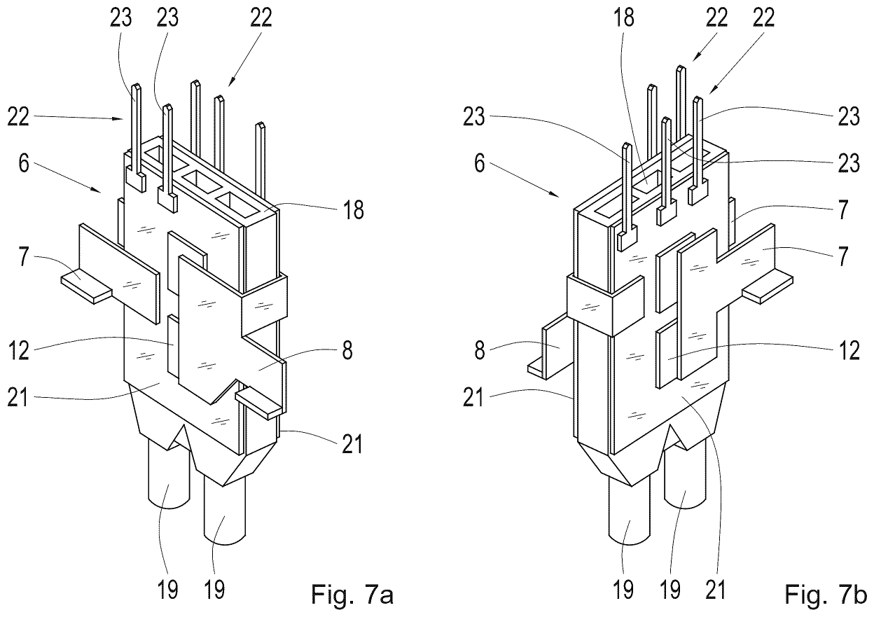

FIGS. 7a, b show three dimensional illustration of another exemplary embodiment of the inventive switch module for the inverter assembly in the preceding figures from different perspectives; and

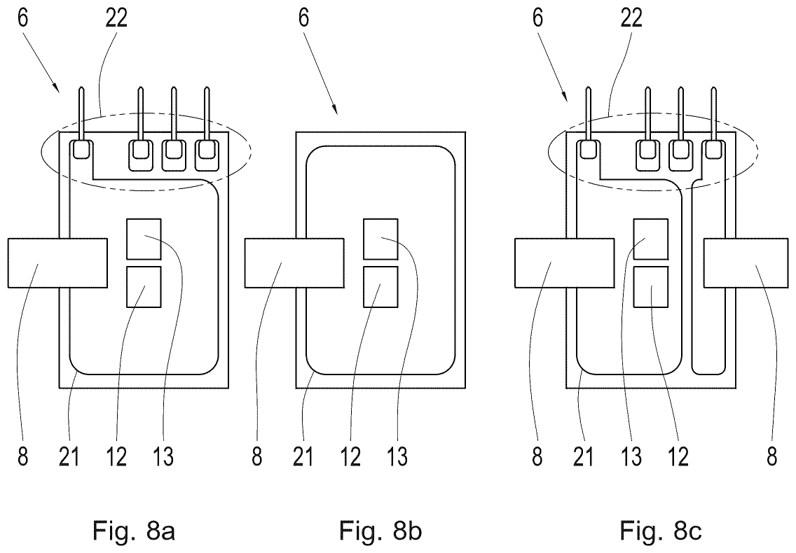

FIGS. 8a, b, c show different variations of a ceramic/copper printed circuit board from above for the switch modules in the preceding figures.

Identical or corresponding components or regions have the same or corresponding reference symbols in the figures. The description relates in the same manner to all of the figures.

FIG. 1 shows an inverter assembly 1 in a schematic, three dimensional illustration, forming an exemplary embodiment of the invention. The inverter assembly 1 can also be referred to as a current inverter. The inverter assembly 1 generates alternating current from a direct current supply 2 obtained from a battery or a fuel cell, for example. It is used in particular to provide alternating current to a vehicle, specifically for an electric motor in the form of a traction motor for the vehicle.

The inverter assembly 1 has an intermediate circuit capacitor 4, which is connected at the input side to the battery or fuel cell (not shown). The inverter assembly 1 also has three phase outputs 5a, b, c, with which the three phases of the alternating current are obtained. The phase outputs 5a, b, c are conductive T-shaped elements, the upright leg of which forms a connection to the electric motor, and the crossbar of which forms a contact for the intermediate circuit capacitor.

There are numerous parallel switch modules 6 that are electrically interconnected between the intermediate circuit capacitor 4 and the phase outputs 5a, b, c. The switch modules 6 each have input connections 7 that come in contact with the intermediate circuit capacitor 4, and output contacts 8, connected in parallel to a phase output 5a, b, c, in particular at the upright leg.

To simplify the description, the intermediate circuit capacitor 4 forms a plane defined by the X and Y-axes, and the vertical direction in the inverter assembly 1 is defined by the Z-axis.

FIG. 2 shows a schematic three dimensional illustration of the connecting region on the inverter assembly 1 from above, where the switch module 6 is located. In this illustration, the phase outputs 5a, b, c on the output side of the switch modules 6 are shown, and the high-side outputs 9a and low-side outputs 9b on the input side for the intermediate circuit capacitor 4 are shown. A DC(+) voltage from the intermediate circuit capacitor 4 is at the high-side outputs 9a, and a DC(−) voltage from the intermediate circuit capacitor 4 is at the low-side outputs 9b. The input connections 7 are connected to the high-side outputs 9a or the low-side outputs 9b. The output connections 8 are connected to the phase outputs 5a, b, c. Each phase output 5a, b, c, has a dedicated group of switch modules 6 connected to a high-side output 9a, and a group of switch modules 6 connected to a low-side output 9b.

FIG. 3 shows a detail of the region of the inverter assembly 1 containing the switch modules 6 in a schematic, three dimensional illustration. This shows that each of the switch modules 6 has a box-shaped, or rectangular, body 10. The switch modules 6 each have a main surface 10a, b that forms the front or back surface of the body 9, or switch module 6. Lateral surfaces encompass the switch module 6, which have significantly smaller surface area than the main surfaces 11a, b.

The main surfaces 11a, b of the module are parallel to the Y-Z plane. In particular, the switch modules 6 are placed on edge in the inverter assembly 1. The switch modules 6 in this exemplary embodiment are stood on edge in a row, such that the main surfaces 11a, b of the switch modules 6 are parallel to one another. The switch modules 6 form a stack. When seen along the X-axis, they are congruent to other. There is a spacing between the switch modules, such that they do not inadvertently come in contact with one another, and can be more effectively cooled.

There are switches 11 and optional, supplementary diodes 12 on the switch modules. These switches 12 and diodes 13 are parallel to the main surfaces 11a, b of the modules, and/or the Y-Z plane. The switches 12 are power semiconductors. The switches 12 and diodes 13 do not have housings. By way of example, the switches 12 are IBGT chips, and the absence of housings minimizes any electrical resistances or thermal resistances, thus increasing the energy efficiency and thermal output.

The input connections 7 each have an input contact surface 14 that is parallel to the X-Y plane and comes in contact with a complementary input contact surface 15 on the high-side output 9a or low-side output 9b. The output connections 8 each have output contact surfaces 16 that are in the X-Y plane and come in contact with the complementary output contact surfaces 17 on the phase outputs 5a, b, c.

Each of the switch modules 6 has a cooling element 18 that is parallel to the main surfaces 11a, b of the modules and/or the Y-Z plane. The cooling element 18 has cooling connections 18 that extend downward and can be inserted into their complementary cooling connections 20 from above.

When the switch module is inserted downward, both the electrical contacts and the connection to the cooling circuit are obtained.

Each switch module 6 has a ceramic/copper printed circuit board 21 that is parallel to the main surfaces 10a, b of the main module 10a, b, and or forms one of these surfaces. The ceramic/copper printed circuit board 21 is formed in particular by a DCB (Direct Copper Bonding) substrate. In particular, switches 12 and/or diodes 13 are placed directly on the DCB substrate, which has the same expansion coefficient as silicon.

In particular, the cooling element 18 is in contact with the ceramic/copper printed circuit board 20. The ceramic/copper printed circuit board 20 has the same surface area as the cooling element 18 in this exemplary embodiment. In particular, the cooling element covers the entire surface of the ceramic/copper printed circuit board 21.

The switch modules 6 each have a control and/or measurement connection 21 that is formed by numerous pins 23 that extend upward.

Consequently, a control and/or measurement printed circuit board 23 can be connected to the switch module 6 by pressing it downward onto the switch module 6.

In summary, the switch modules 6 have input connections 7 and output connections 8 on opposite sides along the Y-axis, and/or cooling connections 19 and control and/or measurement connections on two other opposing sides along the Z-axis.

The inverter assembly 1 exploits the third dimension in order to reduce the necessary installation space for the power semiconductors therein, as can be seen in the drawings.

The inverter assembly 1 is distinctive in that
numerous switch modules 6 can be connected to a single electrical phase,
one or more switch modules 6 form a high-side and low-side switch within an electrical phase, in which the switch modules 6 in a switch can be connected in parallel,
numerous phases, three in the drawings, are obtained for an electric drive,
a one-piece or multi-part intermediate circuit capacitor 4 supplies the switches 12, in particular power semiconductors, with direct current,
there is an intake and outlet for the coolant, such that the switch modules 6 can be cooled in series or in parallel,
there is a printed circuit board in the form of a control and/or measurement printed circuit board 24, with which the switch modules 6 can be controlled, and which can contain the necessary protective circuitry for the semiconductors. The switch modules can be connected to the measurement and control connections with the printed circuit board. Furthermore, the printed circuit board allows numerous dies to be connected in parallel on each topological switch.

Four switch modules 6 in each topological switch are connected to one another in the inverter assembly 1 shown in FIG. 4a. Each switch module 6 contains the power semiconductors forming the switches 12. Each topological switch can also contain some other number of switch modules 6 connected in parallel. The topological switches are connected to a high side and a low side, which can form the alternating current of a phase.

The inverter assembly 1 has three electrical phases, which can be used to power an electric motor. The power semiconductors are connected at one side to the intermediate circuit capacitor 4 by DC+ and DC− connections.

On the lower surface, the cooling elements 18 are inserted in a coolant distributor. The modules are held in place by fasteners 28 in the form of clamps, which are connected to the distributor or the housing. On the upper surface, the measurement and control contacts that form the control and/or measurement connections 22 on the switch module 6 are connected to a printed circuit board forming the control and/or measurement printed circuit board 24, which can contain a driver and control circuit.

FIGS. 4a, b show two alternative arrangements of the switch modules 6 in the inverter assembly 1 with respect to one of the phase outputs 5a, b, c. The switch modules 6 are in two groups in FIG. 4a, which are adjacent to one another. A first group has four switch modules 6, which are in contact on the input side with a low-side output 9b, and a second group has four switch modules 6 that are in contact on the input side with a high-side output 9a of the intermediate circuit capacitor 4. The switch modules 6 in the first group, or their switches 12, therefore form the low-side switches, and the switch modules 6 in the second group, or their switches 12, form the high-side switches. It should be noted that the outputs 9a, b on the intermediate circuit capacitor 4 can have a very simple arrangement.

FIG. 4b shows a distribution of the switch modules 6 in which they are not arranged in groups, but instead are intermixed. In particular, the switch modules are arranged symmetrically to a central plane 25. Consequently, the intermediate circuit capacitor 4 must have more outputs 9a, b. This has the advantage, however, that there is less compensating current when the system is in operation. Specifically, there are two switch modules 6 with high-side switches between each pair of switch modules 6 with low-side switches.

The use of discrete switch modules 6 has the advantage over the use of discrete half bridges that there can be different arrangements of potential switches. FIGS. 4a, b show two different possible arrangements, the left-hand one of which corresponds to that shown in the preceding figures. This arrangement has the advantage that all of the measurement and control connections for a specific potential are adjacent to one another, and the direct current connection can also be obtained easily. The arrangement in FIG. 4b has the advantage of fewer commutating cells, thus minimizing the amount of compensating current needed in the intermediate circuit.

Different semiconductor materials and types can be used in the inverter assembly 1. By way of example, Si, SiC, or GaN can be used as the semiconductor material. The semiconductor types can be, e.g., IGBTs, MOSFETs, or cascodes. Using different semiconductor types and materials allows for arrangements other than those shown in FIGS. 4a, b.

Instead of four parallel switch modules 6, there can be another number connected in parallel.

Different power conductors, e.g. Si-IGBTs, SiC-MOSFETs, SiC cascodes, GaN?, can be used within one electrical phase.

Numerous different types of semiconductors can be used simultaneously in the inverter structure, e.g. Si-IGBTs, and SiC-MOSFETs.

The printed circuit board can have control board functions in addition to the driver functions in an interconnect device. The inverter assembly 1 can also contain numerous interconnect devices.

FIGS. 5a, b, c show schematic three dimensional illustrations of a switch module from different perspectives. They show how part of the body 10 is formed by the ceramic/copper printed circuit board 21, the back surface of which is completely covered by the cooling element 18. The input connection 7 and the output connection 8 extend along the X-axis from opposite sides thereof. The input connection 7 and output connection 8 each have a surface that is in the same plane as the ceramic/copper printed circuit board 21 and comes in contact therewith. Part of the exposed ends of the input connection 7 and output connection 8 is bent 90°, forming the input contact surface 14 and output contact surface 16, both of which point downward. The control and/or measurement connection 22 is formed by pins 23 on the upper surface of the switch module 6, which are for the following functions:
drain
gate
kelvin source
source.

The switch module 6 has a positioning element 26 with an L-shaped profile on the bottom in this exemplary embodiment. The positioning element 26 can be an integral part of the cooling element 18. The positioning element 26 extends beyond the body 10 of the switch module 6 on either side, along the Y-axis, such that it forms positioning plates 27. These positioning plates 27 have an upright leg in the Y-Z plane and a horizontal leg in the X-Y plane.

There are two cooling connections 19 on the bottom of the switch module 6 that extend downward in the shape of a tube.

FIGS. 6a, b show two switch modules 6 installed in the inverter assembly 1. The switch modules 6 are secured in the inverter assembly by fasteners 28. The fasteners 28 are formed by strips and have L-shaped fastening holes 29 that accommodate the positioning plates 27. The holes 29 have the same shape as the positioning plates 27.

The fasteners 28 have mechanical interfaces 30 with which they are held in place when inserted downward. The mechanical interfaces 30 are formed by holes in this exemplary embodiment, into which screws can be inserted to secure the fasteners 28 in the downward direction. The holes 30 are designed to accommodate downward forces, thus holding the switch modules 6 down and connecting them to the cooling connections 19 and pressing the contact surfaces 14, 16 on the connections 7, 8 against the complementary contact surfaces 15, 17 to obtain or improve the electrical contact.

As can be seen in FIGS. 6a, b, one of the switch modules 6 has a high-side switch and one of the switch modules 6 has a low-side switch. To prevent faulty assembly, the positioning plates 27 and fastening holes 29 are mirror-reversed, such that the switch modules 6 can only be inserted correctly.

An alternative design for the switch module 6 is shown in FIGS. 7a, b. The switch modules in this embodiment are half bridges, and each have two switches 12, specifically a high-side switch and a low-side switch. This switch module 6 also has two ceramic/copper printed circuit boards 21, with the cooling element 18 placed therebetween. There is one switch 12 on each ceramic/copper printed circuit board 21. The positioning element 26 is not shown, but it can be placed thereon. The switch module 6 has two input connections 7 that can be connected to the DC+ and DC− inputs on the intermediate circuit capacitor 4. The switch module 6 only has one output connection 8 with which it can be connected to one of the phase outputs 5a, b, c. Each ceramic/copper printed circuit board 21 has its own control and/or measurement connection 22, the pins 23 of which extend upward, along the Z axis.

FIGS. 7a, b therefore show an alternative design for a half bridge assembly, composed of just one component. In this case, the semiconductor for the high side is on one side, and the semiconductor for the low side is on the other side. Each side has its own cooling surface where the cooling element is located, through which the coolant flows in parallel. The AC-plate forming the output connection 8 connects the two topological switches in the assembly to an electric half bridge and extends outward therefrom. There can also be additional control and measurement connections 22, as described in reference to the preceding figures. There can also be positioning plates 27 in the half bridge assembly, with which they can be oriented and secured in place.

The switch module 6 takes advantage of the third dimension to minimize the necessary installation space for the power semiconductors in the inverter assembly 1.

The switch module 6 is distinctive in that
one or more power semiconductors (dies) forming switches 12 for the switch modules 6 can be placed in the Y-Z plane,
the switch module 6 has power connections for the drain and source on opposite sides along the Y-axis,
the switch module 6 is cooled by the cooling element 18, which has an intake and outlet that extend downward, and
the switch module 6 has control and measurement connections (e.g. drain, gate, kelvin-source, source) that extend upward,
the switch module 6 has fastening points (e.g. positioning plates) for the assembly thereof,
instead of two parallel power semiconductors, another number can be used in parallel,
different power semiconductors, e.g. Si-IGBTs, SiC-MOSFETs, SiC cascodes, GaN? Can be used in the chip assembly,
numerous different types of semiconductors can be used simultaneously in the inverter structure, e.g. Si-IGBTs, and SiC-MOSFETs.

One or more power semiconductors can be used in parallel as switches 12 in the switch modules 6, as in FIGS. 5a, b, if a second switch 12 is used instead of the diode 13, such that two SiC-MOSFETs are used, for example, as switches 12. Numerous power semiconductor elements can be also be used in a topological switch, e.g. Si-IGBT+diode (shown by way of example in FIG. 5a), or SiC-cascode. A single control and measurement connection for all of the semiconductors in a switch module 6 extends upward. Each semiconductor could also have individual control and measurement connections.

FIGS. 8a, b, c show different embodiments of the ceramic/copper printed circuit board 21.

The switch 12 and the optional diode 13 are placed on DBC substrate forming a ceramic/copper printed circuit board 21, which connects the drain to the semiconductors, i.e. the switch 12 and the diode 13. The semiconductor elements, i.e. the switch 12 and the diode 13 are placed on copper sections of the ceramic/copper printed circuit board 21, as in the preceding figures.

The ceramic/copper printed circuit board 21, in particular the DBC substrate, can also be used for positioning the control and measurement connections 22. At this point, the copper coating on the ceramic/copper printed circuit board 21 must be divided into numerous parts (FIG. 8a). This can also be part of the lead frame, without touching the DBC substrate (FIG. 8b). The input connection 7 is not connected in FIGS. 5a, b, c with the copper coating of the ceramic/copper printed circuit board 21/DBC substrate. This can be implemented in another assembly, as shown in FIG. 8a, which then requires a connection, e.g. with bond wires, between the input connection and the source contacts on the semiconductor, in particular the switch 12 and/or diode 13. The measurement and control connections 22 that are not connected to their targets by the copper coating in the ceramic/copper printed circuit board 21/DBC substrate, are connected to their targets with connections that are not shown, e.g. bond wires.

The ceramic/copper printed circuit board 21/DBC substrate is connected at the bottom to the cooling element 18 through soldering or sintering, such that heat can be transferred to the coolant, which can be connected to the cooling element with a seal. The cooling element 18 also has a housing over the positioning plates 27 that are needed in order to orient and secure the switch module 6 in a structure, e.g. the inverter structure.

### REFERENCE SYMBOLS

1 inverter assembly
2 DC supply
3 AC supply
4 intermediate circuit capacitor
5a, b, c phase outputs
6 switch module
7 input connection
8 output connection
9a high-side outputs
9b low-side outputs
10 body
11a, b main surfaces of the module
12 switches
13 diodes
14 input contact surfaces
15 complementary input contact surfaces
16 output contact surfaces
17 complementary output contact surface
18 cooling element
19 cooling connection
20 complementary cooling connection
21 ceramic/copper printed circuit board
22 control and/or measurement connection
23 pins
24 control and/or measurement printed circuit board
25 central plane
26 positioning element
27 positioning plate
28 fastener
29 fastening holes
30 mechanical interfaces

1. A switch module for an inverter assembly in a vehicle, comprising:
at least one switch, wherein the switch is a high-side switch or low-side switch;
an input connection for an intermediate circuit capacitor;
an output connection for a phase output;
a body, wherein the body has at least one module main surface, wherein the at least one switch is on the main surface,
wherein the input connection and the output connection are on opposite sides of the switch module and/or extend along an X-axis.

2. The switch module according to claim 1, comprising:
a cooling element, wherein the cooling element is parallel to the main surfaces of the module, and/or parallel to a Y-Z plane.

3. The switch module according to claim 2, wherein the cooling element has a cooling connection, wherein the cooling connection extends downward, along the Z-axis.

4. The switch module according to claim 1, wherein the switch module has a control and/or measurement connection, wherein the control and/or measurement connection extends upward, along the Z-axis.

5. The switch module according to claim 1, wherein the switch is a power semiconductor, wherein the power semiconductor is parallel to the main surfaces of the module, and/or extends in the Y-Z plane.

6. The switch module according to claim 1, wherein the switch module has a ceramic/copper printed circuit board, wherein the ceramic/copper printed circuit board is parallel to the main surfaces of the module, and/or parallel to the Y-Z plane.

7. The switch module according to claim 1, wherein the input connection has an input contact surface and the output connection has an output contact surface,
wherein the contact surfaces are parallel to the X-Y plane, such that contact with the switch module can be obtained, and/or a connection to the cooling connection can be obtained, when the switch module is inserted downward, such that the switch module can be connected to a cooling circuit through the downward insertion, along the Z-axis.

8. The switch module according to claim 1, wherein the switch module has at least one high-side switch and at least one low-side switch.

9. An inverter assembly for a vehicle, comprising:
a plurality of the switch modules according to claim 1;
an intermediate circuit capacitor; and
at least one phase output,
wherein the switches are connected at the input side to the intermediate circuit capacitor and at the output side to the at least one phase output,
wherein the plurality of the switch modules are arranged in a stack, and/or placed upright in a row, with parallel main surfaces in the inverter assembly.

10. The inverter assembly according to claim 9, comprising:
a fastener, wherein the fastener is configured to hold the switch module down, along the Z-axis.

11. The inverter assembly according to claim 9, wherein the parallel main surfaces of the switch modules are parallel to the Y-Z plane, and the intermediate circuit capacitor has at least one capacitor main surface and/or surface extension, wherein the main surface of the capacitor, or the surface extension, is parallel to the X-Y plane.

12. The inverter assembly according to claim 9, wherein each phase output has at least one dedicated high-side switch and at least one dedicated low-side switch.

13. The inverter assembly according to claim 12, wherein each phase output has two or more high-side switches and/or two or more low-side switches,
wherein all the high-side switches of the phase outputs are adjacent to one another, and/or wherein all the low-side switches of a same phase outputs are adjacent to one another.

14. The inverter assembly according to claim 12, wherein each phase output has two or more high-side switches and/or two or more low-side switches, wherein the high-side switches and/or the low-side switches are arranged symmetrically in relation to a central plane.

15. A vehicle comprising:
the inverter assembly according to claim 9, for supplying alternating current to a traction motor in the vehicle.
